(19) United States
(12) Patent Application Publication
(10) Pub. No.: US 2026/0188768 A1
(43) Pub. Date: Jul. 2, 2026

(54) POWER CONTROL METHOD FOR GENERATING A MINIMUM BOOT-UP VOLTAGE OF A SYSTEM

(71) Applicant: MEDIATEK INC., Hsinchu City (TW)

(72) Inventors: Chi-Cheng Liao, Hsinchu City (TW); Jia-You Chuang, Hsinchu City (TW); Jui-Chi Wu, Hsinchu City (TW)

(73) Assignee: MEDIATEK INC., Hsinchu City (TW)

(21) Appl. No.: 19/006,157

(22) Filed: Dec. 30, 2024

(51) Int. Cl. H01M 10/44; G01R 31/389

(52) U.S. Cl. CPC H01M 10/446; G01R 31/389

(57) ABSTRACT

A power control method includes measuring an internal resistance of a battery of the system, measuring a maximum boot-up current of the system, generating a voltage drop according to the internal resistance and the maximum boot-up current, generating a minimum boot-up voltage according to a predetermined voltage and the voltage drop, and performing a boot-up process using a setting with the minimum boot-up voltage where the battery is charged to at least the minimum boot-up voltage in the boot-up process.

### BACKGROUND

For a system, there is a minimum boot-up voltage, and a battery in the system should be charged to the minimum boot-up voltage before the system can be booted successfully. Otherwise, the system will reboot repeatedly and fail to complete the boot-up process. This minimum boot-up voltage is not a fixed voltage. As the battery ages and/or the external environment changes, the minimum boot-up voltage will change accordingly. A suitable solution is in need in this field for dealing with the related problems of obtaining the minimum boot-up voltage.

### SUMMARY

An embodiment provides a power control method for a system. The power control method can include measuring an internal resistance of a battery of the system, measuring a maximum boot-up current of the system, generating a voltage drop according to the internal resistance and the maximum boot-up current, generating a minimum boot-up voltage according to a predetermined voltage and the voltage drop, and performing a boot-up process using a setting with the minimum boot-up voltage where the battery is charged to at least the minimum boot-up voltage in the boot-up process.

Another embodiment provides a power control method for a system. The power control method can include checking number of times of previous boot-up failures, measuring an internal resistance of a battery of the system, measuring a maximum boot-up current of the system, generating a voltage drop according to the internal resistance and the maximum boot-up current, generating a minimum boot-up voltage according to a predetermined voltage and the voltage drop, generating an adjusted minimum boot-up voltage according to the minimum boot-up voltage and the number of times of previous boot-up failures, and performing a boot-up process using a setting with the adjusted minimum boot-up voltage where the battery is charged to at least the adjusted minimum boot-up voltage in the boot-up process.

Another embodiment provides a power control method for a system. The power control method can include capturing a first minimum boot-up voltage from a non-volatile memory, performing a first boot-up process using a setting with the first minimum boot-up voltage wherein a battery of the system is charged to at least the first minimum boot-up voltage in the first boot-up process, checking whether the first boot-up process fails, increasing the first minimum boot-up voltage to generate a second minimum boot-up voltage if the first boot-up process fails, and performing a second boot-up process using a setting with the second minimum boot-up voltage where the battery of the system is charged to at least the second minimum boot-up voltage in the second boot-up process.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a diagram of current changing with time in a boot-up process of a system according to an embodiment.

FIG. 2 illustrates a flowchart of a power control method for the system according to an embodiment.

FIG. 3 illustrates a flowchart of a power control method for the system according to another embodiment.

FIG. 4 illustrates a flowchart of a power control method for the system according to another embodiment.

FIG. 5 illustrates a flowchart of a power control method for the system according to another embodiment.

### DETAILED DESCRIPTION

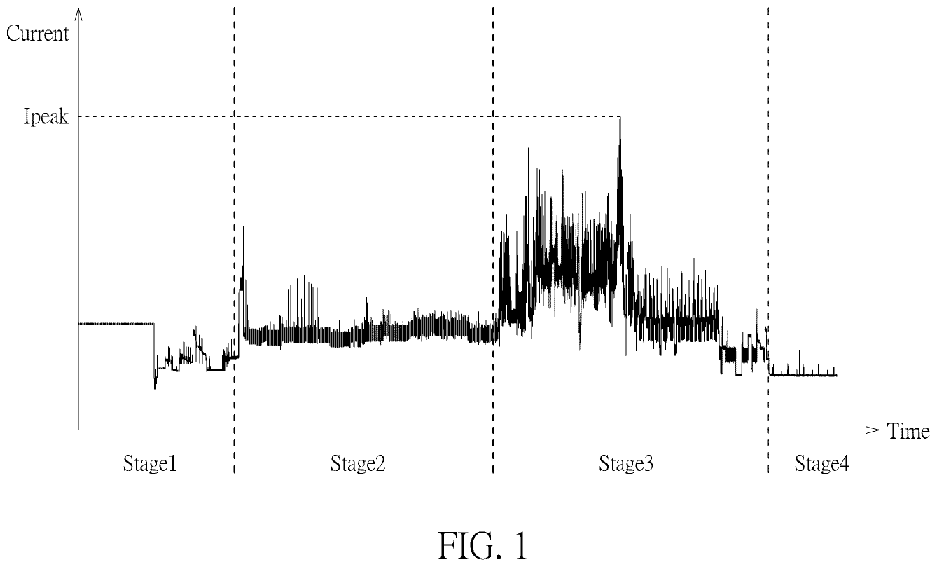

FIG. 1 illustrates a diagram of current changing with time in a boot-up process of a system according to an embodiment. In FIG. 1, the horizontal axis represents time, and the vertical axis represents current of the boot-up process. The boot-up process can include four stages sequentially. The first stage to the fourth stage can include stage 1: a boot rom stage, stage 2: a preloader stage, stage 3: a kernel stage, and stage 4: a boot complete stage.

The boot rom stage can be a starting stage. The preloader stage can be a little kernel (LK) stage. In the preloader stage, a no-load voltage can be obtained, an internal resistance of a battery (expressed as Rac) can be obtained, and a minimum boot-up voltage (expressed as Vminboot) can be adjusted. In the kernel stage, a peak current (i.e. a maximum current in the boot-up process, expressed as Ipeak) can be observed. In the boot complete stage, the minimum boot-up voltage Vminboot can be stored if the boot-up process is completed. FIG. 1 is an example, and embodiments are not limited thereto. For example, in another embodiment, the peak current Ipeak may be observed in another stage.

In the boot-up process, the voltage of the battery in the system may decrease due to IR drop (voltage drop). If the voltage provided by the battery is lower than a threshold, the boot-up process will fail. The threshold may be an undervoltage-lockout (UVLO) voltage (expressed as V_{UVLO}) or a predetermined voltage (expressed as V′). The predetermined voltage V′ can be equal to or larger than undervoltage-lockout voltage V_{UVLO}. It can expressed as: V′≥V_{UVLO}.

The battery should be charged to at least the minimum boot-up voltage Vminboot in the boot-up process. Otherwise, the boot-up process can not be completed successfully. The minimum boot-up voltage Vminboot may vary when the battery ages and/or the environment changes. For example, when the battery ages, the internal resistance of the battery may increase, and the minimum boot-up voltage Vminboot may increase accordingly. When the temperature decreases, the internal resistance of the battery may increase, and the minimum boot-up voltage Vminboot may increase accordingly. Hence, it is required to adjust the minimum boot-up voltage Vminboot for charging the battery appropriately.

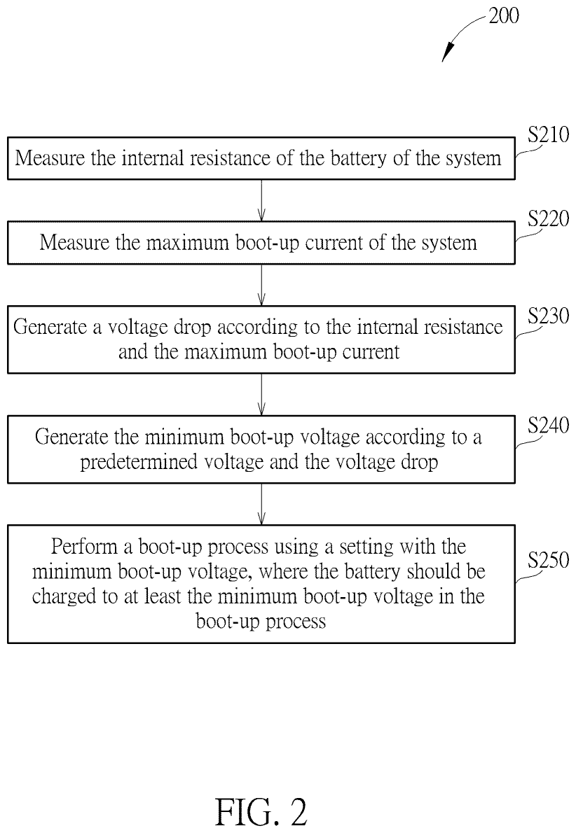

FIG. 2 illustrates a flowchart of a power control method 200 for the system according to an embodiment. The power control method 200 can include the following steps.
Step S210: measure the internal resistance of the battery Rac of the system;
Step S220: measure the maximum boot-up current Ipeak of the system;
Step S230: generate a voltage drop (expressed as Vdrop) according to the internal resistance Rac and the maximum boot-up current Ipeak;
Step S240: generate the minimum boot-up voltage Vminboot according to a predetermined voltage V′ and the voltage drop Vdrop; and
Step S250: perform a boot-up process using a setting with the minimum boot-up voltage Vminboot, where the battery should be charged to at least the minimum boot-up voltage Vminboot in the boot-up process.

In Step S210, the internal resistance of the battery Rac can be measured. The internal resistance of the battery Rac may increase when the battery ages and/or when the temperature decreases. Since the resistance of the battery Rac may change, the minimum boot-up voltage Vminboot may change accordingly.

In Step S230, the voltage drop Vdrop can be positively related to or equal to the product of the internal resistance Rac and the maximum boot-up current Ipeak, and the product can be expressed as Rac*Ipeak.

In Step S240, the predetermined voltage V′ can be equal to or higher than the undervoltage-lockout voltage V_{UVLO} (i.e. V′≥V_{UVLO}), where the system will stop operating if a voltage provided to a power management circuit (a.k.a. PMIC) of the system is lower than the undervoltage-lockout voltage V_{UVLO}.

For example, the difference of the minimum boot-up voltage Vminboot and the voltage drop Vdrop should be greater than the predetermined voltage V′, so the battery can provided a sufficient voltage for the boot-up process. It can be expressed as the following formula:

$${V}^{′} \leq Vminboot - Vdrop . \qquad ( a )$$

If Vdrop=Rac*Ipeak, the formula (a) can be expressed as the following formula:

$${V}^{′} \leq Vminboot - Rac * Ipeak . \qquad ( b )$$

In the formulas (a) and (b), V′≥V_{UVLO} as described above.

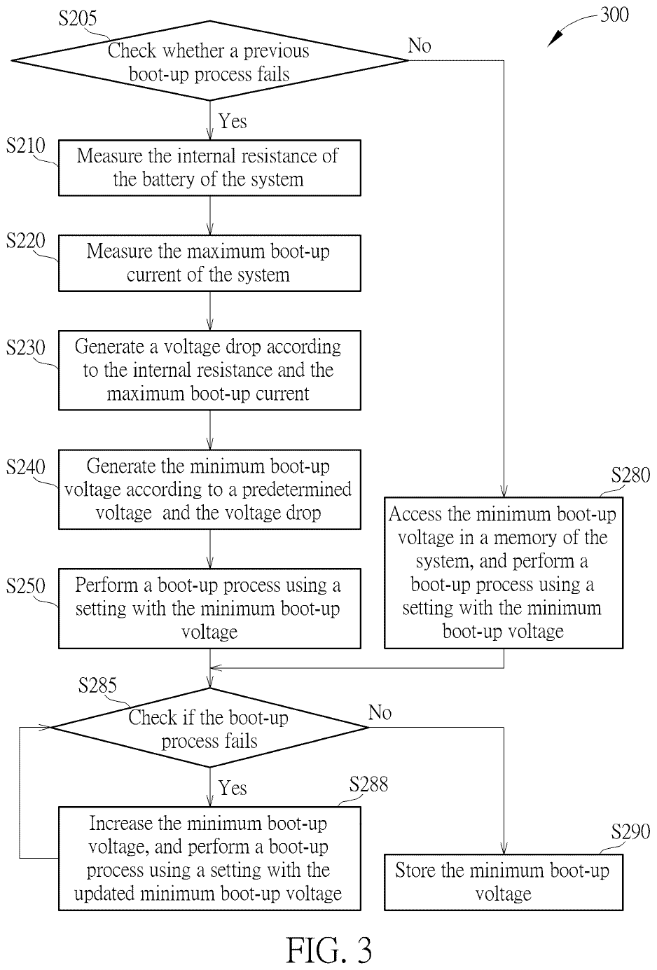

FIG. 3 illustrates a flowchart of a power control method 300 for the system according to another embodiment. The power control method 300 can include the following steps.
Step S205: check whether a previous boot-up process fails; if so, enter Step S210; otherwise, enter Step S280;
Step S210: measure the internal resistance of the battery Rac of the system;
Step S220: measure the maximum boot-up current Ipeak of the system;
Step S230: generate a voltage drop Vdrop according to the internal resistance Rac and the maximum boot-up current Ipeak;
Step S240: generate the minimum boot-up voltage Vminboot according to a predetermined voltage V′ and the voltage drop Vdrop;
Step S250: perform a boot-up process using a setting with the minimum boot-up voltage Vminboot, where the battery should be charged to at least the minimum boot-up voltage Vminboot in the boot-up process; skip to Step S285;
Step S280: access the minimum boot-up voltage Vminboot in a memory of the system, and perform a boot-up process using a setting with the minimum boot-up voltage Vminboot;
Step S285: check if the boot-up process fails; if so, enter Step S288; otherwise, enter Step S290;
Step S288: increase the minimum boot-up voltage Vminboot, and perform a boot-up process using a setting with the updated minimum boot-up voltage Vminboot; enter Step S285; and
Step S290: store the minimum boot-up voltage Vminboot.

In FIG. 3, Step S210 to Step S250 can be similar to that in FIG. 2. In Step S205, if the previous boot-up process fails, Step S210 to Step S250 can be performed to update the minimum boot-up voltage Vminboot for the boot-up process. In Step S205, if the previous boot-up process succeeds, Step S280 can be performed to perform the boot-up process using the original minimum boot-up voltage Vminboot.

In Step S285, if the boot-up process fails, it means the minimum boot-up voltage Vminboot in use may be too low, so the voltage provided by the battery may be insufficient. Hence, Step S288 can be performed to increase the minimum boot-up voltage Vminboot. For example, each time the boot-up process fails, the minimum boot-up voltage Vminboot can be increased by a predetermined value such as 0.1 volts. After the minimum boot-up voltage Vminboot is increased, the voltage provided by the battery (e.g. Vminboot−Ipeak*Rac) can be increased to increase the chance of completing the boot-up process successfully.

After Step S288, Step S285 can be performed to check if the boot-up process can be successfully performed. If the boot-up process succeeds, the flow can enter Step S290 to store the minimum boot-up voltage Vminboot at the time, and perform another process after the boot-up process.

In FIG. 3, Step S205 can be performed in a preloader stage. If the result of Step S205 is “no” (i.e. the previous boot-up process is completed successfully), Step S280 can be performed in the preloader stage. If the result of Step S205 is “yes” (i.e. the previous boot-up process fails), Step S210 to Step S240 can be performed in a little kernel (LK) stage. A kernel stage can follow the little kernel stage, and a boot complete stage can follow the kernel stage. Step S250, Step S288 and Step S290 can be performed in the boot complete stage.

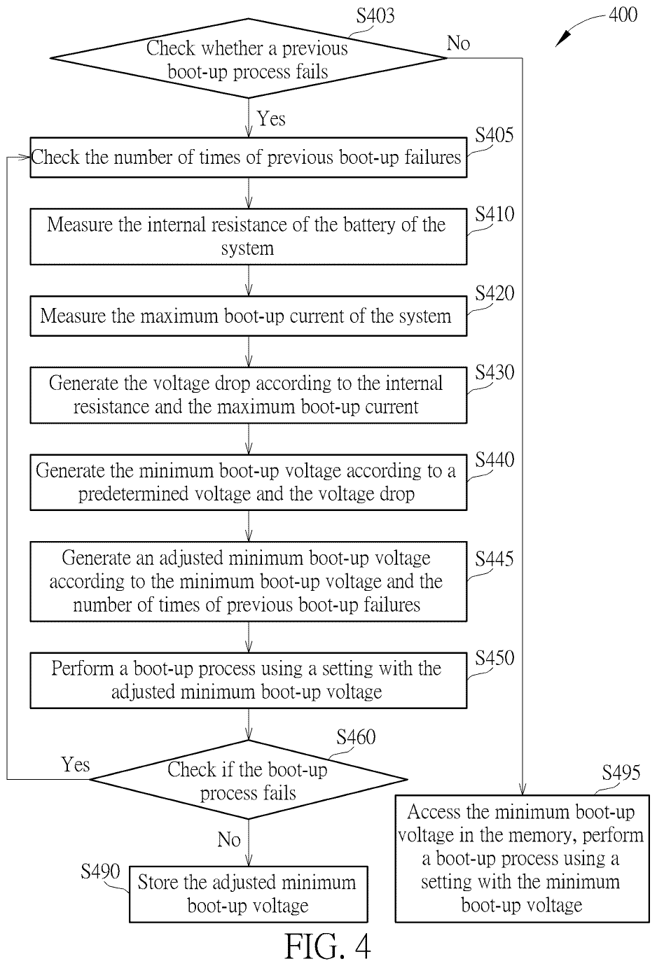

FIG. 4 illustrates a flowchart of a power control method 400 for the system according to another embodiment. The power control method 400 can include the following steps.
Step S403: check whether a previous boot-up process fails; if so, enter Step S405; otherwise, enter Step S495;
Step S405: check the number of times of previous boot-up failures;
Step S410: measure the internal resistance of the battery Rac of the system;
Step S420: measure the maximum boot-up current Ipeak of the system;
Step S430: generate the voltage drop Vdrop according to the internal resistance Rac and the maximum boot-up current Ipeak;
Step S440: generate the minimum boot-up voltage Vminboot according to a predetermined voltage V′ and the voltage drop Vdrop;
Step S445: generate an adjusted minimum boot-up voltage Vminboot′ according to the minimum boot-up voltage Vminboot and the number of times of previous boot-up failures;
Step S450: perform a boot-up process using a setting with the adjusted minimum boot-up voltage Vminboot′, where the battery should be charged to at least the adjusted minimum boot-up voltage Vminboot′ in the boot-up process;
Step S460: check if the boot-up process fails, if so, enter Step S405; otherwise, enter Step S490; and
Step S490: store the adjusted minimum boot-up voltage Vminboot′.
Step S495: access the minimum boot-up voltage Vminboot in the memory, perform a boot-up process using a setting with the minimum boot-up voltage Vminboot.

In Step S405, the number of times of previous boot-up failures can be recorded. The number of times of previous boot-up failures can be stored in a non-volatile memory of the system, such as a register or a plurality of registers in a power management circuit (PMIC).

In FIG. 4, Step S410 to Step S440 can be similar to Step S210 to Step S240 respectively. In Step S430, the voltage drop Vdrop can be positively related to or equal to the product of the internal resistance Rac and the maximum boot-up current Ipeak (i.e. the product can be Rac*Ipeak).

In Step S440, the predetermined voltage V′ can be equal to or higher than a undervoltage-lockout voltage V_{UVLO} (i.e. V′≥V_{UVLO}), where the system will stop operating when a voltage provided to a power management circuit (PMIC) is lower than the undervoltage-lockout voltage V_{UVLO}.

In Step S445, the adjusted minimum boot-up voltage Vminboot′ can be generated by adding a value to the minimum boot-up voltage Vminboot obtained in Step S440, and the value can be larger if the number of times of previous boot-up failures is greater. For example, if the number of times of previous boot-up failures is one, the adjusted minimum boot-up voltage Vminboot′ can be generated by adding 0.1 volts to the minimum boot-up voltage Vminboot obtained in Step S440. If the number of times of previous boot-up failures is two, the adjusted minimum boot-up voltage Vminboot′ can be generated by adding 0.2 volts to the minimum boot-up voltage Vminboot obtained in Step S440.

Step S403 can be perform in a preloader stage following a bootrom stage. Step S405 to Step S450 can be performed in a little kernel (LK) stage following the preloader stage. Step S460 can be performed in a kernel stage following the little kernel (LK) stage. Step S490 can be performed in a boot complete state following the kernel stage.

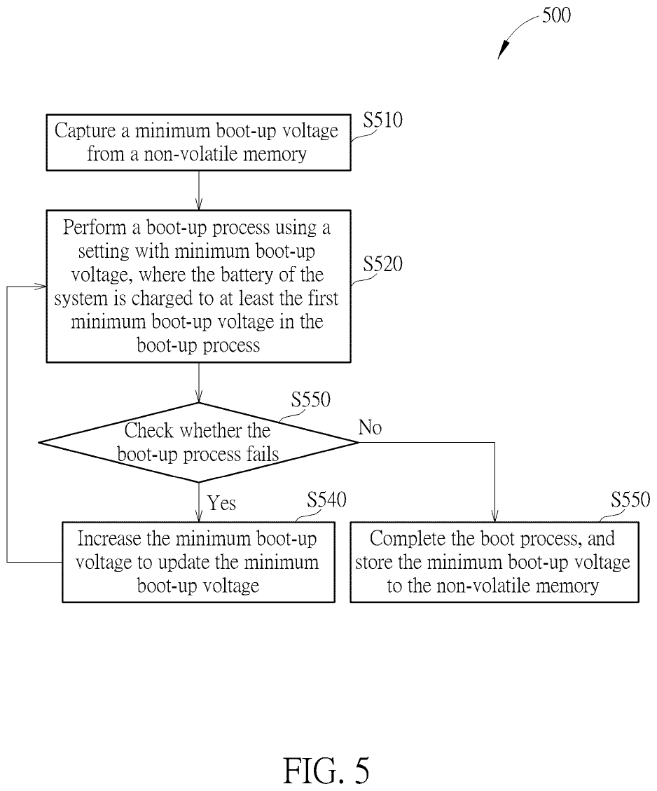

FIG. 5 illustrates s a flowchart of a power control method 500 for the system according to another embodiment. The power control method 500 can include the following steps.
Step S510: capture a minimum boot-up voltage Vminboot from a non-volatile memory;
Step S520: perform a boot-up process using a setting with minimum boot-up voltage Vminboot, where the battery of the system is charged to at least the first minimum boot-up voltage Vminboot in the boot-up process;
Step S530: check whether the boot-up process fails; if so, enter Step S540; otherwise, enter Step S550;
Step S540: increase the minimum boot-up voltage Vminboot to update the minimum boot-up voltage Vminboot; enter Step S520; and
Step S550: complete the boot-up process, and store the minimum boot-up voltage Vminboot to the non-volatile memory.

In FIG. 5, when the boot-up process fails, the minimum boot-up voltage Vminboot can be increased, and the flow can be performed recursively till the boot-up process is completed. In other words, if the boot-up process fails, the minimum boot-up voltage Vminboot can be increased till the boot-up process is completed successfully.

In an embodiment, each time the boot-up process fails, the minimum boot-up voltage Vminboot can be increased by a fix voltage. For example, when the boot-up process fails for the first time, the minimum boot-up voltage Vminboot can be increased by a first value to update the minimum boot-up voltage Vminboot, and when the boot-up process fails for the second time, the updated minimum boot-up voltage Vminboot can be increased by the first value to further update the minimum boot-up voltage Vminboot. In other words, the difference between a first minimum boot-up voltage and a second minimum boot-up voltage can be equal to the difference between the second minimum boot-up voltage and a third minimum boot-up voltage.

In another embodiment, when the boot-up process fails for a plurality of times, the minimum boot-up voltage Vminboot can be increased by different voltages. For example, when the boot-up process fails for the first time, the minimum boot-up voltage Vminboot can be increased by a first value to update the minimum boot-up voltage Vminboot, and when the boot-up process fails for the second time, the updated minimum boot-up voltage Vminboot can be increased by a second value to further update the minimum boot-up voltage Vminboot. The first value and the second value can be different. In other words, the difference between a first minimum boot-up voltage and a second minimum boot-up voltage is not equal to the difference between the second minimum boot-up voltage and a third minimum boot-up voltage. For example, the second value can be greater than the first value. In another example, the second value can be smaller than the first value.

According to the power control methods 200, 300, 400 and 500, the minimum boot-up voltage Vminboot can be calculated and adjusted dynamically. The battery should be charged at least to the adjusted minimum boot-up voltage Vminboot, and a voltage provided by the battery (e.g. Vminboot−Ipeak*Rac) will be sufficient for the boot-up process to effectively avoid the failure of the boot-up process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A power control method for a system, comprising:
measuring an internal resistance of a battery of the system;
measuring a maximum boot-up current of the system;
generating a voltage drop according to the internal resistance and the maximum boot-up current;
generating a minimum boot-up voltage according to a predetermined voltage and the voltage drop; and
performing a boot-up process using a setting with the minimum boot-up voltage, wherein the battery is charged to at least the minimum boot-up voltage in the boot-up process.

2. The power control method of claim 1, wherein the predetermined voltage is equal to a undervoltage-lockout voltage, wherein the system stops operating when a voltage provided to a power management circuit is lower than the undervoltage-lockout voltage.

3. The power control method of claim 1, wherein the predetermined voltage is higher than a undervoltage-lockout voltage, wherein the system stops operating when a voltage provided to a power management circuit is lower than the undervoltage-lockout voltage.

4. The power control method of claim 1, wherein the voltage drop is positively related to a product of the internal resistance and the maximum boot-up current.

5. The power control method of claim 1, wherein the voltage drop is equal to a product of the internal resistance and the maximum boot-up current.

6. The power control method of claim 1, further comprising:
checking whether a previous boot-up process fails;
wherein the internal resistance of the battery of the system is measured if the previous boot-up process fails.

7. The power control method of claim 1, further comprising:
checking if the boot-up process fails; and
increasing the minimum boot-up voltage if the boot-up process fails.

8. A power control method for a system, comprising:
checking number of times of previous boot-up failures;
measuring an internal resistance of a battery of the system;
measuring a maximum boot-up current of the system;
generating a voltage drop according to the internal resistance and the maximum boot-up current;
generating a minimum boot-up voltage according to a predetermined voltage and the voltage drop;
generating an adjusted minimum boot-up voltage according to the minimum boot-up voltage and the number of times of previous boot-up failures; and
performing a boot-up process using a setting with the adjusted minimum boot-up voltage, wherein the battery is charged to at least the adjusted minimum boot-up voltage in the boot-up process.

9. The power control method of claim 8, wherein the adjusted minimum boot-up voltage is generated by adding a value to the minimum boot-up voltage, and the value is larger if the number of times of previous boot-up failures is greater.

10. The power control method of claim 8, wherein the predetermined voltage is equal to a undervoltage-lockout voltage, wherein the system stops operating when a voltage provided to a power management circuit is lower than the undervoltage-lockout voltage.

11. The power control method of claim 8, wherein the predetermined voltage is higher than a undervoltage-lockout voltage, wherein the system stops operating when a voltage provided to a power management circuit is lower than the undervoltage-lockout voltage.

12. The power control method of claim 8, wherein the voltage drop is positively related to a product of the internal resistance and the maximum boot-up current.

13. The power control method of claim 8, wherein the voltage drop is equal to a product of the internal resistance and the maximum boot-up current.

14. The power control method of claim 8, wherein the number of times of previous boot-up failures is stored in a non-volatile memory.

15. A power control method for a system, comprising:
capturing a first minimum boot-up voltage from a non-volatile memory;
performing a first boot-up process using a setting with the first minimum boot-up voltage, wherein a battery of the system is charged to at least the first minimum boot-up voltage in the first boot-up process;
checking whether the first boot-up process fails;
increasing the first minimum boot-up voltage to generate a second minimum boot-up voltage if the first boot-up process fails; and
performing a second boot-up process using a setting with the second minimum boot-up voltage, wherein the battery of the system is charged to at least the second minimum boot-up voltage in the second boot-up process.

16. The power control method of claim 15, further comprising:
checking whether the second boot-up process fails;
increasing the second minimum boot-up voltage to generate a third minimum boot-up voltage if the second boot-up process fails; and
performing a third boot-up process using a setting with the third minimum boot-up voltage, wherein the battery of the system is charged to at least the third minimum boot-up voltage in the third boot-up process;
wherein a difference between the first minimum boot-up voltage and the second minimum boot-up voltage is equal to a difference between the second minimum boot-up voltage and the third minimum boot-up voltage.

17. The power control method of claim 15, further comprising:
checking whether the second boot-up process fails;
increasing the second minimum boot-up voltage to generate a third minimum boot-up voltage if the second boot-up process fails; and
performing a third boot-up process using a setting with the third minimum boot-up voltage, wherein the battery of the system is charged to at least the third minimum boot-up voltage in the third boot-up process;
wherein a difference between the first minimum boot-up voltage and the second minimum boot-up voltage is not equal to a difference between the second minimum boot-up voltage and the third minimum boot-up voltage.
